(19) United States
(12) Patent Application Publication
(10) Pub. No.: US 2026/0082673 A1
(43) Pub. Date: Mar. 19, 2026

(54) SEMICONDUCTOR DEVICE

(71) Applicants: KABUSHIKI KAISHA TOSHIBA, Kawasaki-shi, Kanagawa (JP); Toshiba Electronic Devices & Storage Corporation, Kawasaki-shi (JP)

(72) Inventors: Taira TABAKOYA, Chiba, Chiba (JP); Eitaro MIYAKE, Tachikawa, Tokyo (JP)

(73) Assignees: KABUSHIKI KAISHA TOSHIBA, Kawasaki-shi, Kanagawa (JP); Toshiba Electronic Devices & Storage Corporation, Kawasaki-shi, Kanagawa (JP)

(21) Appl. No.: 19/305,035

(22) Filed: Aug. 20, 2025

(30) Foreign Application Priority Data
Sep. 17, 2024 (JP) 2024-160087

(51) Int. Cl. H10D 80/20; H01L 23/00; H01L 23/31; H01L 23/373; H01L 25/07

(52) U.S. Cl. CPC H10D 80/251; H10W 40/255; H10W 74/114; H10W 90/00; H10W 72/884; H10W 90/734; H10W 90/754

(57) ABSTRACT

According to one embodiment, a semiconductor device includes first and second circuit boards, a first semiconductor chip, a first column and a first terminal. The second circuit board is provided above the first circuit board. The first semiconductor chip is provided between the first and second circuit boards. The first column is provided between the first and second circuit boards. The first terminal is provided at an end of the first circuit board in a first direction, and has a first cut. The first cut of the first terminal has a first part, a second part, and a third part. The first part extends from an end of the first terminal in the first direction. The second part is continuous with the first part and extends in a second direction crossing the first direction. The third part is continuous with the second part and extends in the first direction.

### CROSS-REFERENCE TO RELATED APPLICATIONS

This application is based upon and claims the benefit of priority from Japanese Patent Application No. 2024-160087, filed Sep. 17, 2024, the entire contents of which are incorporated herein by reference.

### FIELD

Embodiments described herein relate generally to a semiconductor device.

### BACKGROUND

A semiconductor device that includes an insulated circuit board on which a semiconductor chip is mounted is known.

### BRIEF DESCRIPTION OF THE DRAWINGS

FIG. 1 is a perspective view of an external structure of a semiconductor device according to an embodiment.

FIG. 2 is a perspective view of a main terminal of the semiconductor device according to the embodiment.

FIG. 3 is a circuit diagram showing a circuit configuration of the semiconductor device according to the embodiment.

FIG. 4 is a plan view of an internal structure of the semiconductor device according to the embodiment.

FIGS. 5 and 6 are cross-sectional views of the internal structure of the semiconductor device according to the embodiment.

FIG. 7 is a plan view of the main terminal of the semiconductor device according to the embodiment.

FIG. 8 is a cross-sectional view of the main terminal of the semiconductor device according to the embodiment.

FIG. 9 is a plan view of another main terminal of the semiconductor device according to the embodiment.

### DETAILED DESCRIPTION

In general, according to one embodiment, a semiconductor device includes a first circuit board, a second circuit board, a first semiconductor chip, a first column, and a first terminal. The second circuit board is provided above the first circuit board. The first semiconductor chip is provided between the first circuit board and the second circuit board. The first column is provided between the first circuit board and the second circuit board. The first terminal is provided at an end of the first circuit board in a first direction, and has a first cut. The first cut of the first terminal has a first part, a second part, and a third part. The first part extends from an end of the first terminal in the first direction. The second part is continuous with the first part and extends in a second direction crossing the first direction. The third part is continuous with the second part and extends in the first direction.

An embodiment will be described below with reference to the drawings. The description will use the same reference symbols for the components having the same functions and configurations. The embodiment described below merely shows an exemplary apparatus or method for implementing the technical concept of the embodiment, and the materials, shapes, structures, arrangements, and the like of the components are not limited to those described below.

### Embodiments

A semiconductor device according to an embodiment will be described. A semiconductor device includes a semiconductor chip and two insulated circuit boards that sandwich the semiconductor chip from above and below, and has a package structure that holds them with a molding member. The semiconductor device is a power module and is used for, for example, driving a motor of an electric vehicle.

### 1. External Structure of Semiconductor Device

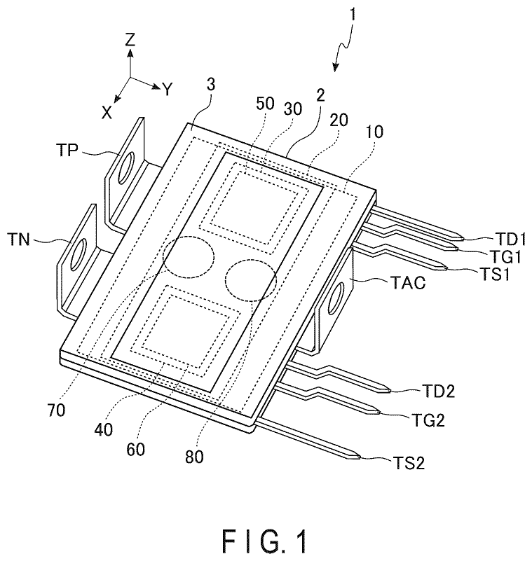

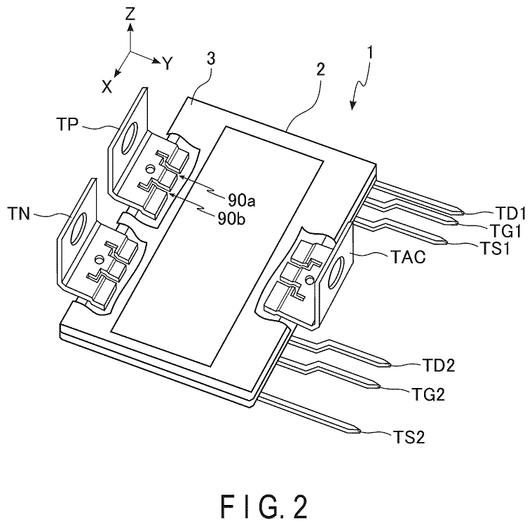

First, an external structure of a semiconductor device 1 of an embodiment will be described with reference to FIGS. 1 and 2. FIG. 1 is a perspective view of an external structure of the semiconductor device 1 according to an embodiment. An XYZ orthogonal coordinate system is used in the description below. The X-direction corresponds to a longitudinal direction of a contour of the semiconductor device 1 excluding terminals. The Y-direction corresponds to a width direction of the contour of the semiconductor device 1 excluding the terminals. The Z-direction corresponds to a thickness direction of the contour of the semiconductor device 1 excluding the terminals and is also referred to as an upper direction and a lower direction.

The semiconductor device 1 includes a main part 2, main terminals TP, TN, and TAC, and a plurality of lead terminals TG1, TG2, TD1, TD2, TS1, and TS2. The main part 2 includes a molding member 3, a lower insulated circuit board 10, an upper insulated circuit board 20, semiconductor chips (or semiconductor elements) 30 and 40, chip spacers (or columns) 50 and 60, and inter-board spacers (or columns) 70 and 80.

FIG. 2 is a perspective view of the main terminals TP, TN, and TAC of the semiconductor device 1 of the embodiment. FIG. 2 shows the main terminals TP, TN, and TAC seen through the molding member 3.

The main terminals TP and TN are provided at one end of the main part 2 in the Y-direction. The main terminal TAC and the lead terminals TG1, TG2, TD1, TD2, TS1, and TS2 are provided at the other end of the main part 2 in the Y-direction. The lead terminals TG1, TD1, and TS1 and the lead terminals TG2, TD2, and TS2 are arranged in such a manner as to interpose the main terminal TAC therebetween. Each of the main terminals TP, TN, and TAC has cuts (or notches) 90a and 90b.

### 2. Circuit Configuration of Semiconductor Device

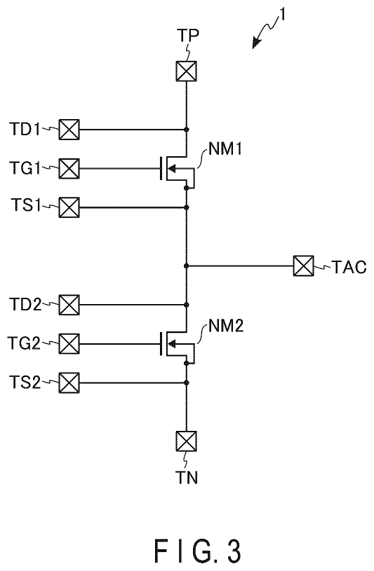

Next, a circuit configuration of the semiconductor device 1 of the embodiment will be described with reference to FIG. 3. FIG. 3 is a circuit diagram showing a circuit configuration of the semiconductor device of the embodiment.

The semiconductor device 1 includes, for example, a half-bridge circuit. The semiconductor device 1 includes transistors NM1 and NM2, and also includes the main terminals TP, TN, and TAC, and the lead terminals TG1, TG2, TD1, TD2, TS1, and TS2, as described above.

Each of the transistors NM1 and NM2 is, for example, an n-type MOS field-effect transistor.

Each of the main terminals TP and TN is a power supply terminal of the semiconductor device 1. The main terminal TP is supplied with a positive power supply voltage. The main terminal TP is also referred to as a “P terminal.” The main terminal TN is supplied with a negative power supply voltage. The main terminal TN is also referred to as an “N terminal.” The main terminal TAC is an output terminal of the semiconductor device 1. An alternating-current voltage is output from the main terminal TAC. The main terminal TAC is also referred to as an “AC terminal.”

Each of the lead terminals TG1 and TG2 is a control terminal of the semiconductor device 1. Each of the lead terminals TD1, TD2, TS1, and TS2 is a terminal for monitoring an operation of the semiconductor device 1. The lead terminal TD1 senses a voltage of a drain of the transistor NM1. The lead terminal TS1 senses a voltage of a source of the transistor NM1. The lead terminal TD2 senses a voltage of a drain of the transistor NM2. The lead terminal TS2 senses a voltage of a source of the transistor NM2.

The drain of the transistor NM1 is coupled to the main terminal TP. The source of the transistor NM1 is coupled to the main terminal TAC. The gate of the transistor NM1 is coupled to the lead terminal TG1. The drain of the transistor NM2 is coupled to the main terminal TAC. The source of the transistor NM2 is coupled to the main terminal TN. The gate of the transistor NM2 is coupled to the lead terminal TG2.

The drain of the transistor NM1 is coupled to the lead terminal TD1. The source of the transistor NM1 is coupled to the lead terminal TS1. The drain of the transistor NM2 is coupled to the lead terminal TD2. The source of the transistor NM2 is coupled to the lead terminal TS2.

### 3. Internal Structure of Semiconductor Device

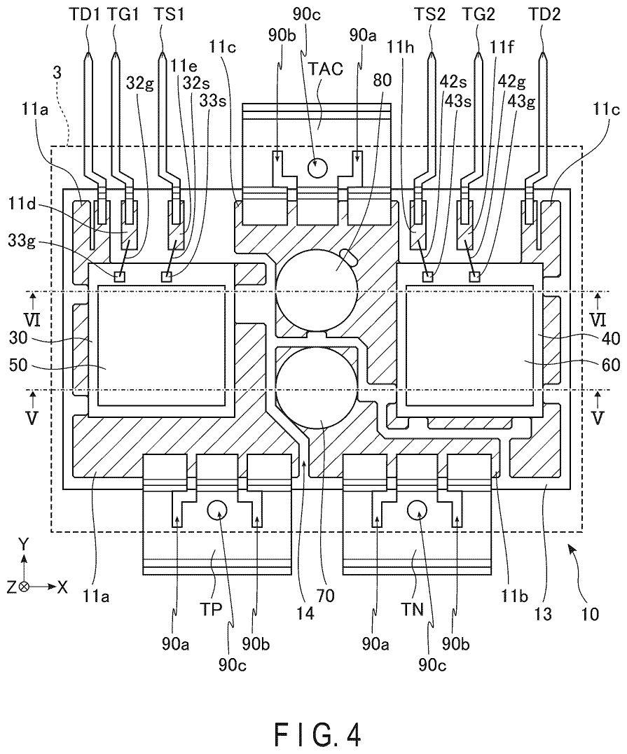

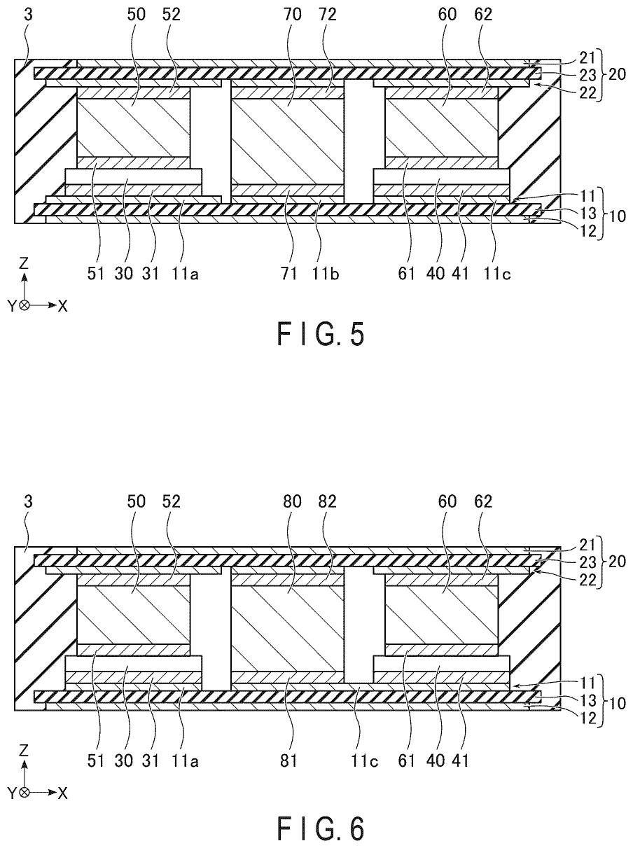

Next, an internal structure of the semiconductor device 1 of the embodiment will be described with reference to FIGS. 4, 5, and 6. FIG. 4 is a plan view of an internal structure of the semiconductor device 1 of the embodiment. FIG. 5 is a cross-sectional view taken along a line V-V in FIG. 4. FIG. 6 is a cross-sectional view taken along a line VI-VI in FIG. 4. The plan view of FIG. 4 shows a configuration on the insulated circuit board 10 seen through the insulated circuit board 20 and the molding member 3. In the figures below, the directions indicated by arrows in the X-direction, the Y-direction, and the Z-direction are referred to as a “+X-direction,” a “+Y-direction”, and a “+Z-direction”, respectively, and the directions opposite to the directions indicated by arrows are referred to a “−X-direction,” a “−Y-direction”, and a “−Z-direction”, respectively.

As shown in FIG. 4, the semiconductor chip 30 is provided on one end side of the insulated circuit board 10 in the X-direction, and the semiconductor chip 40 is provided on the other end side of the insulated circuit board 10 in the X-direction. The inter-board spacers 70 and 80 are arranged between the semiconductor chip 30 and the semiconductor chip 40 in the Y-direction. As shown in FIGS. 5 and 6, the inter-board spacers 70 and 80 are arranged between the insulated circuit board 10 and the insulated circuit board 20.

The insulated circuit board 10 includes a conductive plate (or conductive layer) 11, a conductive plate (or conductive layer) 12, and a ceramic board 13. The ceramic board 13 is arranged between the conductive plate 11 and the conductive plate 12. That is, the conductive plate 11 is arranged on an upper surface of the ceramic board 13, and the conductive plate 12 is arranged on a lower surface of the ceramic board 13. Each of the conductive plates 11 and 12 has a thickness of, for example, about 0.4 mm. The conductive plates 11 and 12 include, for example, copper. The ceramic board 13 is formed of an insulating material and has electrically insulating properties.

The conductive plate 11 has a slit 14 formed by removing a part of the conductive plate 11 in such a manner as to form a pattern shape. That is, the slit 14 is a groove formed in the conductive plate 11 by removing a part of the conductive plate 11.

The conductive plate 11 is separated into three conductive patterns (or circuit patterns or conductive layers) 11a, 11b, and 11c by the slit 14. The conductive patterns 11a, 11b, and 11c are electrically insulated from each other.

Likewise, the insulated circuit board 20 includes a conductive plate (or conductive layer) 21, a conductive plate (or conductive layer) 22, and a ceramic board 23. The ceramic board 23 is arranged between the conductive plate 21 and the conductive plate 22. That is, the conductive plate 21 is arranged on an upper surface of the ceramic board 23, and the conductive plate 22 is arranged on a lower surface of the ceramic board 23. Each of the conductive plates 21 and 22 has a thickness of, for example, about 0.4 mm. The conductive plates 21 and 22 include, for example, copper. The ceramic board 23 is formed of an insulating material and has electrically insulating properties.

Although not shown, the conductive plate 22 is separated by a slit into multiple conductive patterns (or circuit patterns or conductive layers) that are electrically insulated from each other.

The semiconductor chip 30 is provided on the conductive pattern 11a via a conductive member such as a solder material 31. The chip spacer 50 is provided on the semiconductor chip 30 via a conductive member such as a solder material 51. The conductive patterns of the conductive plate 22 are arranged on the chip spacer 50 via a conductive member such as a solder material 52.

The semiconductor chip 30 includes the transistor NM1. The semiconductor chip 30 has the gate, source, and drain of the transistor NM1 as an electrode.

For example, the drain of the semiconductor chip 30 is electrically coupled to the conductive pattern 11a via the solder material 31. The source of the semiconductor chip 30 is electrically coupled to the chip spacer 50 via the solder material 51.

The semiconductor chip 30 and the chip spacer 50 are arranged between the insulated circuit board 10 and the insulated circuit board 20. The chip spacer 50 is arranged between the insulated circuit board 20 and the semiconductor chip 30. The chip spacer 50 has, for example, a quadrilateral shape when seen from the Z-direction, and has a shape of a column having a thickness in the Z-direction. The chip spacer 50 includes a conductive material and has electrical conductivity. Thus, the source of the semiconductor chip 30 is electrically coupled to the conductive patterns of the conductive plate 22 via the solder material 51, the chip spacer 50, and the solder material 52. The chip spacer 50 also functions as a heat dissipation path that lets the heat generated in the semiconductor chip 30 out to the insulated circuit board 20.

The inter-board spacer 70 is provided on the conductive pattern 11b via a conductive member such as a solder material 71. The conductive patterns of the conductive plate 22 are arranged on the inter-board spacer 70 via a conductive member such as a solder material 72.

The inter-board spacer 70 has, for example, a circular shape when seen from the Z-direction, and has a shape of a column having a thickness in the Z-direction. In one example, the inter-board spacer 70 has a shape of a cylinder or a rectangular column. The inter-board spacer 70 includes a conductive material and has electrical conductivity. Thus, the conductive pattern 11b is electrically coupled to the conductive patterns of the conductive plate 22 via the solder material 71, the inter-board spacer 70, and the solder material 72.

The semiconductor chip 40 is provided on the conductive pattern 11c via a conductive member such as a solder material 41. The chip spacer 60 is provided on the semiconductor chip 40 via a conductive member such as a solder material 61. The conductive patterns of the conductive plate 22 are arranged on the chip spacer 60 via a conductive member such as a solder material 62.

The semiconductor chip 40 includes the transistor NM2. The semiconductor chip 40 has the gate, source, and the drain of the transistor NM2 as an electrode.

For example, the drain of the semiconductor chip 40 is electrically coupled to the conductive pattern 11c via the solder material 41. The source of the semiconductor chip 40 is electrically coupled to the chip spacer 60 via the solder material 61.

The semiconductor chip 40 and the chip spacer 60 are arranged between the insulated circuit board 10 and the insulated circuit board 20. The chip spacer 60 is arranged between the insulated circuit board 20 and the semiconductor chip 40. The chip spacer 60 has, for example, a quadrilateral shape when seen from the Z-direction, and has a shape of a column having a thickness in the Z-direction. The chip spacer 60 includes a conductive material and has electrical conductivity. Thus, the source of the semiconductor chip 40 is electrically coupled to the conductive patterns of the conductive plate 22 via the solder material 61, the chip spacer 60, and the solder material 62. The chip spacer 60 also functions as a heat dissipation path that lets the heat generated in the semiconductor chip 40 out to the insulated circuit board 20.

The inter-board spacer 80 is provided on the conductive pattern 11c via a conductive member such as a solder material 81. The conductive patterns of the conductive plate 22 are arranged on the inter-board spacer 80 via a conductive member such as a solder material 82.

The inter-board spacer 80 has, for example, a circular shape when seen from the Z-direction, and has a shape of a column having a thickness in the Z-direction. In one example, the inter-board spacer 80 has a shape of a cylinder or a rectangular column. The inter-board spacer 80 includes a conductive material and has electrical conductivity. Thus, the conductive pattern 11c is electrically coupled to the conductive patterns of the conductive plate 22 via the solder material 81, the inter-board spacer 80, and the solder material 82.

As shown in FIG. 4, the main terminals TP and TN are provided at one end of the insulated circuit board 10 in the Y-direction. The main terminal TAC is provided at the other end of the insulated circuit board 10 in the Y-direction. Each of the main terminals TP, TN, and TAC has a conductive member such as a metal member including copper and the like. Each of the main terminals TP, TN, and TAC has a thickness of, for example, 0.8 mm.

The main terminal TP is arranged on one end of the conductive pattern 11a in the Y-direction. The main terminal TP is bonded to the conductive pattern 11a via a conductive member such as a solder material. That is, the main terminal TP is electrically coupled to the conductive pattern 11a via a solder material. The main terminal TN is arranged on one end of the conductive pattern 11b in the Y-direction. The main terminal TN is bonded to the conductive pattern 11b via a conductive member such as a solder material. That is, the main terminal TN is electrically coupled to the conductive pattern 11b via a solder material. The main terminal TAC is arranged on the other end of the conductive pattern 11c in the Y-direction. The main terminal TAC is bonded to the conductive pattern 11c via a conductive member such as a solder material. That is, the main terminal TAC is electrically coupled to the conductive pattern 11c via a solder material.

The plurality of lead terminals TG1, TG2, TD1, TD2, TS1, and TS2 are provided at the other end of the insulated circuit board 10 in the Y-direction.

The conductive pattern 11a and the conductive patterns 11d and 11e are arranged on the other end side of the insulated circuit board 10 in the Y-direction with respect to the semiconductor chip 30. Each of the conductive patterns 11d and 11e has an island-shaped pattern.

The lead terminal TG1 is bonded to the conductive pattern 11d via a conductive member such as a solder material. The conductive pattern 11d is coupled to a pad 33g of the semiconductor chip 30 by a bonding wire 32g. The pad 33g is coupled to the gate of the semiconductor chip 30. Thus, the lead terminal TG1 is electrically coupled to the gate of the semiconductor chip 30 via the conductive pattern 11d, the bonding wire 32g, and the pad 33g.

The lead terminal TD1 is bonded to the conductive pattern 11a via a conductive member such as a solder material. The conductive pattern 11a is coupled to the drain of the semiconductor chip 30. Thus, the lead terminal TD1 is electrically coupled to the drain of the semiconductor chip 30 via the conductive pattern 11a.

The lead terminal TS1 is bonded to the conductive pattern 11e via a conductive member such as a solder material. The conductive pattern 11e is coupled to a pad 33s of the semiconductor chip 30 by a bonding wire 32s. The pad 33s is coupled to the source of the semiconductor chip 30. Thus, the lead terminal TS1 is electrically coupled to the source of the semiconductor chip 30 via the conductive pattern 11e, the bonding wire 32s, and the pad 33s.

The conductive pattern 11c and the conductive patterns 11f and 11h are arranged on the other end side of the insulated circuit board 10 in the Y-direction with respect to the semiconductor chip 40. Each of the conductive patterns 11f and 11h has an island-shaped pattern.

The lead terminal TG2 is bonded to the conductive pattern 11f via a conductive member such as a solder material. The conductive pattern 11f is coupled to a pad 43g of the semiconductor chip 40 by a bonding wire 42g. The pad 43g is coupled to the gate of the semiconductor chip 40. Thus, the lead terminal TG2 is electrically coupled to the gate of the semiconductor chip 40 via the conductive pattern 11f, the bonding wire 42g, and the pad 43g.

The lead terminal TD2 is bonded to the conductive pattern 11c via a conductive member such as a solder material. The conductive pattern 11c is coupled to the drain of the semiconductor chip 40. Thus, the lead terminal TD2 is electrically coupled to the drain of the semiconductor chip 40 via the conductive pattern 11c.

The lead terminal TS2 is bonded to the conductive pattern 11h via a conductive member such as a solder material. The conductive pattern 11h is coupled to a pad 43s of the semiconductor chip 40 by a bonding wire 42s. The pad 43s is coupled to the source of the semiconductor chip 40. Thus, the lead terminal TS2 is electrically coupled to the source of the semiconductor chip 40 via the conductive pattern 11h, the bonding wire 42s, and the pad 43s.

As shown in FIG. 4, each of the main terminals TP, TN, and TAC has the cuts 90a and 90b and a hole 90c. Seen from the Z-direction in FIG. 4, that is, seen from the upper side with respect to a plane of the conductive plate 11 of the insulated circuit board 10 (or seen from the orthogonal directions), the cut 90a of the main terminal TP extends in the −Y-direction from one end of the main terminal TP in the Y-direction, then extends in the −X-direction, and further extends in the −Y-direction. The cut 90b of the main terminal TP extends in the −Y-direction from one end of the main terminal TP in the Y-direction, then extends in the +X-direction, and further extends in the −Y-direction. The cuts 90a and 90b of the main terminal TN respectively have substantially the same shape as the shapes of the cuts 90a and 90b of the main terminal TP.

Seen from the Z-direction in FIG. 4, the cut 90a of the main terminal TAC extends in the +Y-direction from one end of the main terminal TAC in the Y-direction, then extends in the +X-direction, and further extends in the +Y-direction. The cut 90b of the main terminal TAC extends in the +Y-direction from one end of the main terminal TAC in the Y-direction, then extends in the −X-direction, and further extends in the +Y-direction.

Seen from the Z-direction in FIG. 4, the hole 90c of each of the main terminals TP, TN, and TAC has a circular shape. The hole 90c is arranged between the cut 90a and the cut 90b in the X-direction.

The cuts 90a and 90b of each of the main terminals TP, TN, and TAC will be detailed below.

### 4. Structure of Main Terminals

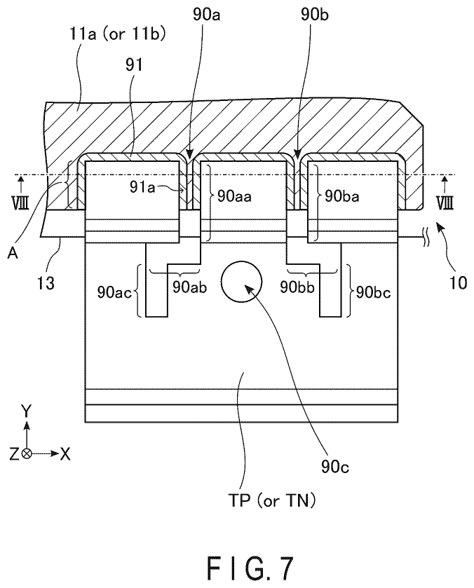

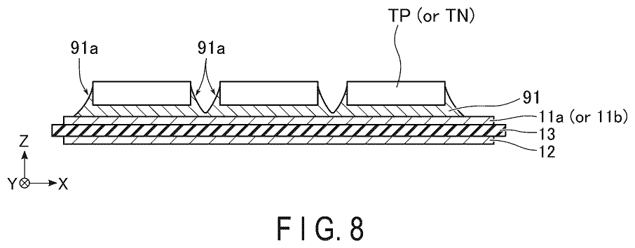

Next, a structure of the main terminals TP, TN, and TAC of the semiconductor device 1 of the embodiment will be detailed with reference to FIGS. 7, 8, and 9. FIG. 7 is a plan view of the main terminal TP (or TN) of the semiconductor device 1 of the embodiment. FIG. 8 is a cross-sectional view taken along a line VIII-VIII in FIG. 7, and shows a cross-sectional structure of the main terminal TP and the insulated circuit board 10 including the conductive pattern 11a.

The main terminal TP has a shape in which a plate-shaped metal member along an XY plane extends in the −Y-direction, slightly bends in the +Z-direction, then extends in the −Y-direction, and further bends in the +Z-direction.

Seen from the Z-direction, the main terminal TP has a rectangular shape (or polygonal shape). As described above, the main terminal TP has the cuts 90a and 90b and the hole 90c.

As shown in FIG. 7, the cut 90a has, from one end of the main terminal TP in the Y-direction, a first part 90aa extending in the −Y-direction, a second part 90ab extending in the −X-direction, and a third part 90ac extending in the −Y-direction. The second part 90ab is continuous with an end of the first part 90aa. The third part 90ac is continuous with an end of the second part 90ab.

The first part 90aa has a first width in the X-direction and has a first length in the Y-direction. The second part 90ab has a second width in the Y-direction and has a second length in the X-direction. The third part 90ac has a third width in the X-direction and has a third length in the Y-direction. The first width, the second width, and the third width may be the same as or different from each other. The first length, the second length, and the third length may be the same as or different from each other. For example, the first length is larger than the second length and the third length, and the third length is larger than the second length.

The cut 90b is arranged close to the cut 90a in the X-direction. The cut 90b has a line-symmetric structure with respect to the cut 90a with a line along the Y-direction as an axis of symmetry.

The cut 90b has, from one end of the main terminal TP in the Y-direction, a first part 90ba extending in the −Y-direction, a second part 90bb extending in the +X-direction, and a third part 90bc extending in the −Y-direction. The second part 90bb is continuous with an end of the first part 90ba. The third part 90bc is continuous with an end of the second part 90bb.

Like the cut 90a, the first part 90ba has a first width in the X-direction and has a first length in the Y-direction. The second part 90bb has a second width in the Y-direction and has a second length in the X-direction. The third part 90bc has a third width in the X-direction and has a third length in the Y-direction. The first width, the second width, and the third width may be the same as or different from each other. The first length, the second length, and the third length may be the same as or different from each other. For example, the first length may be larger than the second length and the third length, and the third length larger than the second length.

Also, as shown in FIGS. 7 and 8, a conductive member such as a solder material 91 is arranged between the main terminal TP and the conductive pattern 11a. In a region A shown in FIG. 7, the main terminal TP is coupled to the conductive pattern 11a via the solder material 91. A fillet 91a of the solder material 91 is formed on a side surface of the main terminal TP.

The first parts 90aa and 90ba of the cuts 90a and 90b of the main terminal TP are arranged in the region A where the main terminal TP is coupled to the conductive pattern 11a via the solder material 91. Thus, the fillet 91a is formed not only on a side surface on an outer perimeter of the main terminal TP but also on a side surface of the first part 90aa of the cut 90a and on a side surface of the first part 90ba of the cut 90b.

The first length of the first part 90aa in the Y-direction is equal to or greater than a length of the region A in the Y-direction. In other words, the first length of the first part 90aa in the Y-direction is equal to or greater than a length of the solder material 91 between the conductive pattern 11a and the main terminal TP in the Y-direction. Likewise, the first length of the first part 90ba in the Y-direction is equal to or greater than the length of the region A in the Y-direction. In other words, the first length of the first part 90ba in the Y-direction is equal to or greater than the length of the solder material 91 between the conductive pattern 11a and the main terminal TP in the Y-direction.

The structure of the main terminal TN is substantially the same as the structure of the main terminal TP. Seen from the Z-direction, the main terminal TN has a rectangular shape (or polygonal shape). The main terminal TN has the cuts 90a and 90b and the hole 90c. The structures of the cuts 90a and 90b and the hole 90c of the main terminal TN are substantially the same as the structures of the cuts 90a and 90b and the hole 90c of the main terminal TP.

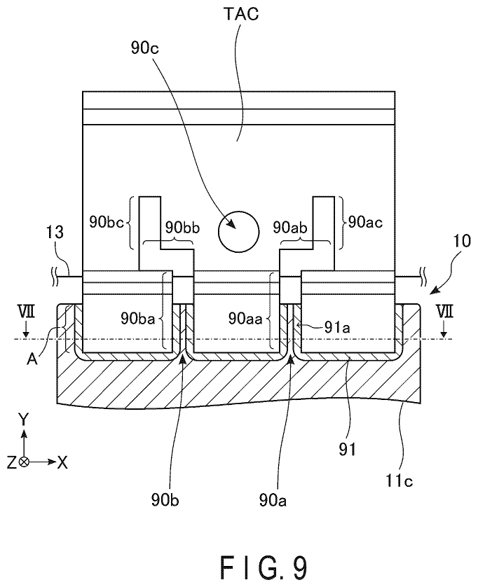

FIG. 9 is a plan view of the main terminal TAC of the semiconductor device 1 of the embodiment. The structure of the main terminal TAC is also substantially the same as the structure of the main terminal TP. The main terminal TAC has a line-symmetric structure with respect to the main terminal TP with a line along the X-direction as an axis of symmetry and is also arranged near the center of the insulated circuit board 10 in the X-direction.

The main terminal TAC has a shape in which a plate-shaped metal member along the XY plane extends in the +Y-direction, slightly bends in the +Z-direction, then extends in the +Y-direction, and further bends in the +Z-direction.

Seen from the Z-direction, the main terminal TAC has a rectangular shape (or polygonal shape). The main terminal TAC has the cuts 90a and 90b and the hole 90c. The structures of the cuts 90a and 90b and the hole 90c of the main terminal TAC are substantially the same as the structures of the cuts 90a and 90b and the hole 90c of the main terminal TP.

According to the embodiment described above, a semiconductor device having a highly reliable terminal structure can be provided.

In the configuration of the embodiment, the first parts 90aa and 90ba of the cuts 90a and 90b of the main terminal TP are arranged in the region A where the main terminal TP (or TN or TAC) is coupled to the conductive pattern 11a (or 11b or 11c).

Thus, the fillet 91a of the solder material 91 is formed on a side surface on an outer perimeter of the main terminal TP and on a side surface of the main terminal TP where the first parts 90aa and 90ba are arranged. As a result, it is possible to form the fillet 91a in more regions on the side surface of the main terminal TP, allowing robust coupling of the main terminal TP to the conductive pattern 11a of the insulated circuit board 10.

Also, in the configuration of the embodiment, the main terminal TP (or TN or TAC) has the cuts 90a and 90b. When electric current passes through the semiconductor device 1, the semiconductor device 1 may have a high temperature due to heat generation. Thus, the insulated circuit boards 10 and 20 and the main terminal TP may be deformed by stress and the solder material that bonds the main terminal TP and the conductive pattern 11a may be peeled off. As described above, since the main terminal TP has the cuts 90a and 90b, it is possible to alleviate the stress generated in the main terminal TP. Thus, it is possible to prevent the solder material that bonds the main terminal TP and the conductive pattern 11a from being peeled off.

In the configuration of the embodiment, the cuts 90a and 90b of the main terminal TP (or TN or TAC) are covered with the molding member 3. Thus, the molding member 3 enters the cuts 90a and 90b, strengthening the adhesion or bond between the molding member 3 and the main terminal TP. As a result, it is possible to form a strong structure that can reduce the occurrence of breakage or the like of the main terminal TP and the molding member 3 even if a force is applied to the main terminal TP due to an external or internal stress. For example, it is possible to form a strong structure that can reduce the deformation of the main terminal TP and the molding member 3, that is, improve the durability against a tensile force even if a force of pulling toward outside is applied to the main terminal TP from the outside or even if a pulling force is applied to the main terminal TP due to an internal stress.

As explained above, according to the semiconductor device 1 of the embodiment, it is possible to form a highly reliable terminal structure.

The embodiment described above explains an example in which a semiconductor device constitutes a MOS field-effect transistor (i.e., MOSFET); however, a semiconductor device may constitute another switching element such as an insulated gate bipolar transistor (IGBT). If a semiconductor device constitutes an IGBT, the source corresponds to an emitter, and the drain corresponds to a collector.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first circuit board;
a second circuit board provided above the first circuit board;
a first semiconductor chip provided between the first circuit board and the second circuit board;
a first column provided between the first circuit board and the second circuit board; and
a first terminal provided at an end of the first circuit board in a first direction, the first terminal having a first cut,
wherein the first cut of the first terminal has a first part, a second part, and a third part,
the first part extends from an end of the first terminal in the first direction,
the second part is continuous with the first part and extends in a second direction crossing the first direction, and
the third part is continuous with the second part and extends in the first direction.

2. The semiconductor device according to claim 1, further comprising a conductive member between the first circuit board and the first terminal, the conductive member coupling the first circuit board and the first terminal,
wherein the first part of the first cut of the first terminal is arranged a region where the conductive member is arranged.

3. The semiconductor device according to claim 2, wherein the first part of the first cut has a length equal to or greater than a length of the conductive member in the first direction.

4. The semiconductor device according to claim 2, wherein a fillet of the conductive member is provided on a side surface of the first terminal having the first part of the first cut.

5. The semiconductor device according to claim 1, further comprising a molding member covering the first circuit board and the second circuit board,
wherein the first cut of the first terminal is covered with the molding member.

6. The semiconductor device according to claim 1, wherein
the first circuit board includes a first conductive layer, a second conductive layer, and a first insulated board between the first conductive layer and the second conductive layer, and
the second circuit board includes a third conductive layer, a fourth conductive layer, and a second insulated board between the third conductive layer and the fourth conductive layer.

7. The semiconductor device according to claim 1, wherein
the first terminal includes a second cut in the second direction with respect to the first cut,
the second cut includes a fourth part, a fifth part, and a sixth part,
the fourth part extends from an end of the first terminal in the first direction,
the fifth part is continuous with the fourth part and extends in the second direction, and
the sixth part is continuous with the fifth part and extends in the first direction.

8. The semiconductor device according to claim 1, further comprising:
a second semiconductor chip between the first circuit board and the second circuit board;
a second column between the first circuit board and the second circuit board;
a third column between the first semiconductor chip and the second circuit board; and
a fourth column between the second semiconductor chip and the second circuit board.

9. The semiconductor device according to claim 1, wherein the first column has a circular shape when seen from a third direction and has a thickness in the third direction, the third direction being orthogonal to the first direction and the second direction.

10. The semiconductor device according to claim 1, wherein the first column electrically couples the first circuit board and the second circuit board.

11. The semiconductor device according to claim 8, wherein
each of the first column and the second column has a circular shape when seen from a third direction and has a thickness in the third direction, the third direction being orthogonal to the first direction and the second direction, and
each of the third column and the fourth column has a quadrilateral shape when seen from the third direction and has a thickness in the third direction.

12. The semiconductor device according to claim 8, wherein
each of the first column and the second column electrically couples the first circuit board and the second circuit board,
the third column electrically couples the first semiconductor chip and the second circuit board, and
the fourth column electrically couples the second semiconductor chip and the second circuit board.

13. The semiconductor device according to claim 1, further comprising a second terminal at an end of the first circuit board in the first direction, the second terminal being arranged in the second direction with respect to the first terminal, the second terminal having a cut,
wherein the cut of the second terminal has a seventh part, an eighth part, and a ninth part,
the seventh part extends from an end of the second terminal in the first direction,
the eighth part is continuous with the seventh part and extends in the second direction, and
the ninth part is continuous with the eighth part and extends in the first direction.

14. The semiconductor device according to claim 13, further comprising a third terminal at another end of the first circuit board in the first direction, the third terminal having a cut,
wherein the cut of the third terminal has a tenth part, an eleventh part, and a twelfth part,
the tenth part extends from an end of the third terminal in the first direction,
the eleventh part is continuous with the tenth part and extends in the second direction, and
the twelfth part is continuous with the eleventh part and extends in the first direction.

15. The semiconductor device according to claim 14, further comprising a second semiconductor chip between the first circuit board and the second circuit board,
wherein the first semiconductor chip includes a first MOS field-effect transistor,
the second semiconductor chip includes a second MOS field-effect transistor,
the first terminal is electrically coupled to a drain of the first MOS field-effect transistor,
the second terminal is electrically coupled to a source of the second MOS field-effect transistor, and
the third terminal is electrically coupled to a source of the first MOS field-effect transistor and a drain of the second MOS field-effect transistor.

16. The semiconductor device according to claim 1, wherein the first semiconductor chip includes a MOS field-effect transistor.

17. The semiconductor device according to claim 1, wherein the first semiconductor chip includes an insulated gate bipolar transistor (IGBT).

18. The semiconductor device according to claim 6, wherein the first conductive layer, the second conductive layer, the third conductive layer, and the fourth conductive layer include copper.

19. The semiconductor device according to claim 6, wherein the first insulated board and the second insulated board include a ceramic board.
